(19) United States
(12) Patent Application Publication
(10) Pub. No.: US 2011/0049383 A1
(43) Pub. Date: Mar. 3, 2011

(54) ION IMPLANTER AND ION IMPLANT METHOD THEREOF

(75) Inventors: ZHIMIN WAN, Sunnyvale, CA (US); JOHN D. POLLOCK, Rowley, MA (US); DON BERRIAN, Topsfield, MA (US)

(73) Assignee: ADVANCED ION BEAM TECHNOLOGY, INC., San Jose, CA (US)

(21) Appl. No.: 12/553,946

(22) Filed: Sep. 3, 2009

(51) Int. Cl. C23C 14/48; H01J 27/02

(52) U.S. Cl. 250/423 R; 250/492.3

(57) ABSTRACT

An ion implanter and an ion implant method for achieving a two-dimensional implantation on a wafer are disclosed. The ion implanter includes an ion source, a mass analyzer, a wafer driving mechanism, an aperture mechanism, and an aperture driving mechanism. The ion source and the mass analyzer are capable of providing an ion beam. The wafer driving mechanism is configured to drive a wafer along only a first direction. The aperture mechanism has an aperture for filtering the ion beam before the wafer is implanted. The aperture driving mechanism is configured to drive the aperture along a second direction intersecting the first direction. By moving the wafer and the aperture along different directions separately, the projection of the ion beam can achieve a two-dimensional implantation on the wafer. Here, at least one of the directions is optionally parallel to the longer dimension of the two-dimensional cross-section of the ion beam.

### BACKGROUND OF THE INVENTION

1. Field of the Invention

The present invention generally relates to an ion implanter and implant method, and more particularly, relates to an ion implanter and an ion implant method that achieves a two-dimensional scan by moving a wafer and an aperture for filtering an ion beam along different directions separately.

2. Description of the Prior Art

Ion implantation is a popular and important processing step performed during semiconductor manufacture. To effectively implant a wafer with a required dose distribution, a two-dimensional scan path is typically used.

FIG. 1A is a simplified diagram of a conventional ion implanter 100. The conventional implanter 100 includes an ion source 110 and a mass analyzer 120. The ion source 110 is used to generate ions that are analyzed by the mass analyzer 120 before the required ions are implanted into the wafer 10.

FIG. 1B shows a top view of the wafer 10 depicted in FIG. 1A. Several popular ion implant methods exist for achieving a two-dimensional scan of the ion beam 20 on the wafer 10. If the wafer 10 is fixed, the ion beam 20 can be moved along both the X-axis and the Y-axis. If the ion beam 20 is fixed, the wafer 10 can be moved along both the X-axis and the Y-axis. Also, both the ion beam 20 and the wafer 10 can be moved along the X-axis and the Y-axis simultaneously.

When the ion beam 20 is movable, it is difficult to precisely control the properties of the implantation on the wafer 10. For example, the incident angle between the implanted ion beam and the surface of the wafer varies among different portions of the wafer 10. This variance causes the wafer 10 to be non-uniformly implanted whereby an additional step may be required to improve the uniformity.

Hence, a popular implementation involves fixing the ion beam and moving the wafer to achieve the two-dimensional scan, regardless of whether a spot ion beam or a ribbon ion beam is used.

However, when the size of the wafer 10 is increased, the required movement distance of the wafer 10 must also be increased to ensure proper implantation of the whole wafer 10. Hence, the cost and complexity of the mechanism for moving the wafer 10 are correspondingly increased. Of course, a solution is to increase the height of the ion beam 20, such that the wafer 10 can be properly implanted by the ion beam 20 without having to significantly move the wafer 10. However, increasing the height of ion beam 20 causes the uniformity of the ion beam 20 to be decreased, so that the problem of meeting the required movement distance of the wafer 10 still persists and remains significant.

For the disadvantages mentioned above, there is a need to propose a novel ion implanter and a novel ion implant method for achieving the two-dimensional scan.

### SUMMARY OF THE INVENTION

The present invention provides a new approach for achieving a two-dimensional scan. According to a feature of the invention, conventional two-dimensional movement of the wafer is replaced by a one-dimensional movement of the wafer and a one-dimensional movement of an aperture for filtering an ion beam before the wafer is implanted. Hence, when the wafer and the aperture are moved along different directions respectively, a two-dimensional scan of a projection of the ion beam on the wafer can be achieved without using the conventional two-dimensional movement of the wafer.

One embodiment is an ion implant method. The ion implant method includes the following steps. Initially, a wafer and an ion beam are provided. Also an aperture mechanism (e.g., panel) is provided with an aperture capable of filtering the ion beam before the wafer is implanted, especially to filter out partial ion beam and only allow other portions of the ion beam to be implanted. Next, the wafer is moved along a first direction, and the aperture mechanism is moved along a second direction intersecting with the first direction respectively, such that a projection of the ion beam is two-dimensionally scanned over the wafer.

Another embodiment is an ion implanter. The ion implanter includes one or more of an ion source, a mass analyzer, a wafer driving mechanism (e.g., advancer), an aperture mechanism, and an aperture driving mechanism (e.g., advancer). The ion source is capable of generating an ion beam, and the mass analyzer is capable of analyzing the ion beam. The wafer driving mechanism is configured to drive a wafer to be implanted by the ion beam, wherein the wafer is, is capable of being, is operated to be, or is configured to be, movable only along a first direction. The aperture mechanism has an aperture that is configured to filter an ion beam before the wafer is implanted. The aperture driving mechanism is used for driving the aperture mechanism, wherein the aperture is, is capable of being, is operated to be, and/or is configured to be, movable along a second direction. A two-dimensional scan of the ion beam on the wafer is achieved by both the wafer driving mechanism and the aperture driving mechanism driving the wafer and the aperture along different directions.

### BRIEF DESCRIPTION OF THE DRAWINGS

FIG. 1A is a simplified diagram of a conventional ion implanter;

FIG. 1B shows a top view of the wafer depicted in FIG. 1A;

FIG. 2A is a sectional view of an ion implanter with an aperture mechanism in accordance with an embodiment of the present invention;

FIG. 2B and FIG. 2C show sectional and top views respectively of the aperture mechanism depicted in FIG. 2A;

FIG. 3 shows a flow diagram of an ion implant method in accordance with an embodiment of the present invention;

FIG. 4A to FIG. 4G show ion implant steps as an example of the method depicted in FIG. 3;

FIG. 5A to FIG. 5G show ion implant steps as another example of the method depicted in FIG. 3; and

FIG. 6A and FIG. 6B show steps of optionally adjusting the filtered ion beam according to an embodiment of the invention.

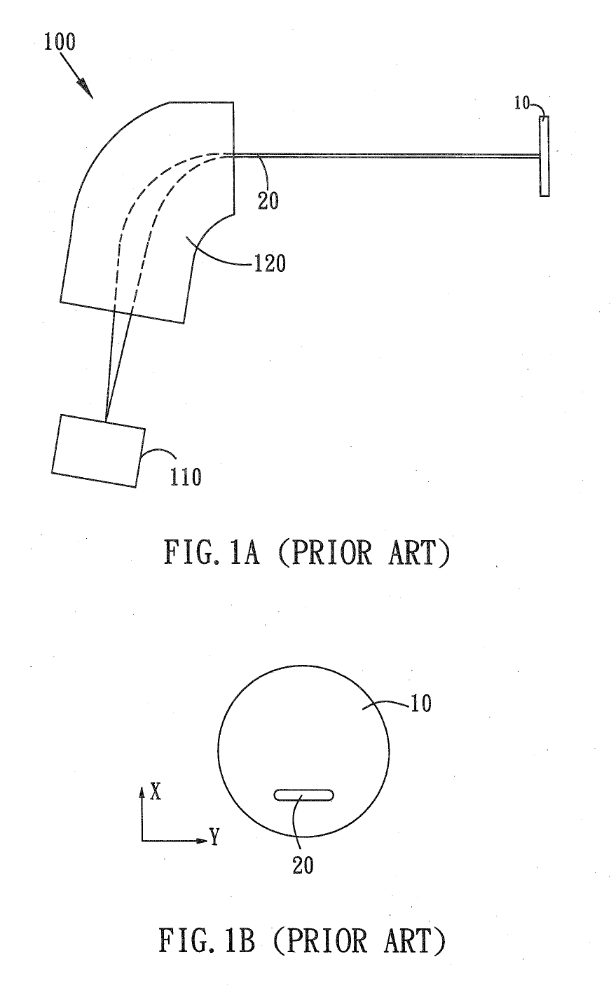

### DETAILED DESCRIPTION OF THE INVENTION

A detailed description of the present invention will be discussed in connection with the following embodiments, which are intended not to limit the scope of the present invention but rather to be adaptable for other applications. While the drawings are illustrated in detail, it is appreciated that the quantity of the disclosed components may be greater or less than that disclosed except for instances expressly restricting such components.

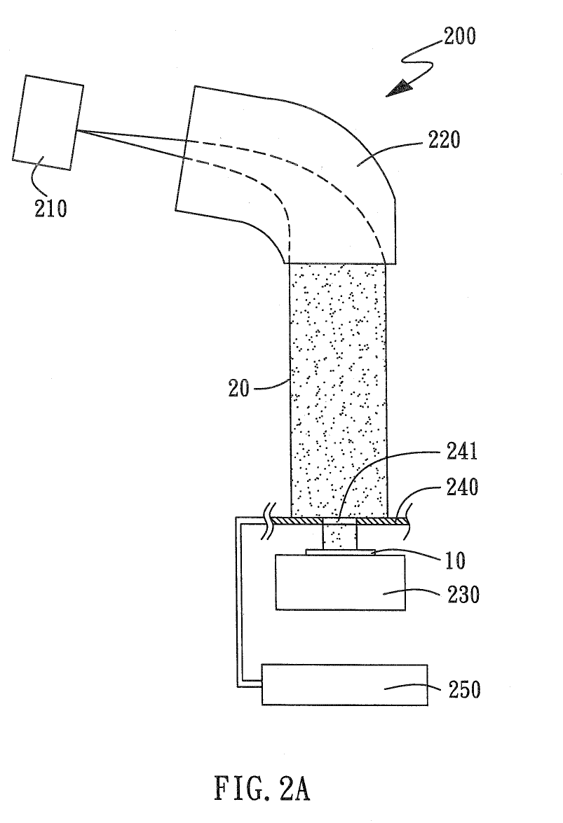

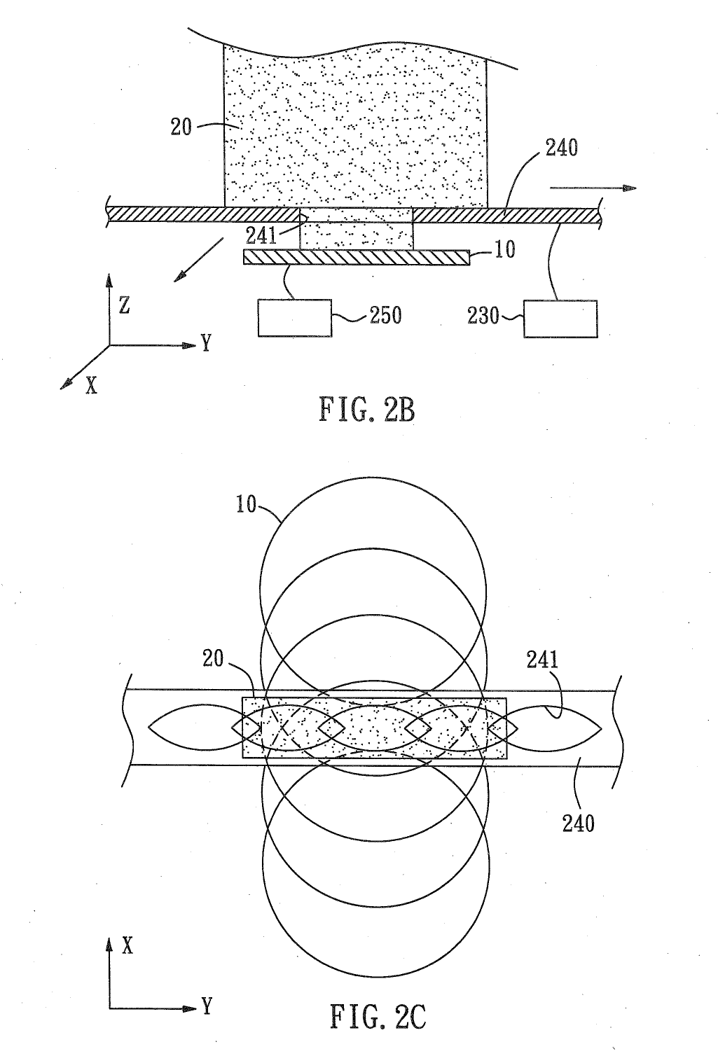

FIG. 2A is a sectional view of an ion implanter 200 in accordance with an embodiment of the present invention. The ion implanter 200 includes an ion source 210, a mass analyzer 220, a wafer driving mechanism (e.g., advancer) 230, an aperture mechanism (e.g., panel) 240, and an aperture driving mechanism (e.g., advancer) 250. The ion source 210 is capable of generating an ion beam, and the mass analyzer 220 is capable of filtering out ions without desired kinds/energies from the ion beam 20. A combination of both the ion source 210 and the mass analyzer 220 can be regarded as an ion beam assembly, because their function is generating the ion beam to be implanted into the wafer. The aperture mechanism 240 has an aperture 241 such that only a portion of the ion beam is allowed to be implanted into the wafer 10. Moreover, the wafer driving mechanism 230 and the aperture driving mechanism 250 are configured to move the wafer 10 and the aperture mechanism 240 separately. Note that the embodiment is not intended to particularly limit the details of the wafer driving mechanism 230 and the aperture driving mechanism 250, except for limiting their functions. Hence, FIG. 2A shows only their existence without providing particular details such as their positions or sizes.

FIG. 2B and FIG. 2C show sectional and top views of the operation of the aperture mechanism 240 depicted in FIG. 2A respectively. The X-axis is perpendicular to the Y-axis. The wafer driving mechanism 230 is used for driving a wafer 10 only along the X-axis. The aperture driving mechanism 250 is used for driving the aperture mechanism 240 such that the aperture 241 is moved along only the Y-axis. Accordingly, a two-dimensional scan of the ion beam 20 on the wafer 10 is achieved by the movements of the wafer 10 and the aperture 241. Herein, the aperture 241 is only moved across the ion beam 20 along the Y-axis, and the wafer 10 is only moved across the ion beam 20 along the X-axis. Hence, a two-dimensional scan on the X-Y plane, intersecting with the ion beam 20, is achieved.

By comparison with the conventional two-dimensional scan, one advantage of the embodiment is clear. In the prior art, the wafer is moved along both the X-axis and the Y-axis. In contrast, in the inventive embodiment, the wafer is moved along the X-axis, and the aperture 241 is moved along the Y-axis. Clearly, the size of the aperture mechanism 240 can be significantly smaller than that of the wafer 10, especially the size along the X-axis. Note that the aperture mechanism 240 is used only to provide the aperture 241, in other words, to block portions of the ion beam 20 other than the portion directly passing through the aperture 241. Hence, along the Y-axis, the mechanism for driving the aperture mechanism 240 provided by the embodiment can be significantly simpler, even cheaper, than that of the mechanism for driving the wafer 10 required by the prior art.

Although FIG. 2A to FIG. 2C show the situation where the movement direction of the wafer 10 is perpendicular to the movement direction of the aperture 241, the invention need not be so limited. Indeed, the only requirement is that the wafer 10 and the aperture 241 be moved along different directions. According to another aspect, to effectively achieve two-dimension scanning, it is better that one or more of the wafer 10 and the aperture 241 be moved in a direction of a long axis of the projection of the ion beam (e.g., as shown). That is, it may be advantageous to perform such movement parallel to the longer dimension of the two-dimensional cross-section of the ion beam.

Furthermore, according to an optional feature, the wafer 10 is moved with a first velocity and the aperture mechanism 240 is moved with a second velocity, wherein the first velocity is independent of the second velocity, and one or more (e.g., both) of the first velocity and the second velocity are adjustable. Therefore, the ion beam projection can be scanned through different points of the wafer 10 by an adjustable velocity, such that different portions of the wafer 10 can be scanned with different velocities. When a non-uniform implantation over the wafer 10 is required, or when a different scan rate is an important factor of implantation over the wafer 10, the option is valuable.

By analogy, the function of the aperture 241 can be likened to that of a raster, whereby for instance only a portion of the wafer 10 exposed by the aperture 241 is implanted. Therefore, when the aperture 241 is moved, different portions of the wafer 10 can be implanted without corresponding movement of the wafer 10 or adjusting of the mass analyzer 220.

Owing to its movability over the wafer 10, another advantage of the embodiment is the motion of the aperture 241 being flexible such that one or more of the scan path and the scan rate of the aperture 241 over the wafer 10 are adjustable. Therefore, depending on the kind of dose distribution over the wafer 10 that is required, each of the scan path and the scan rate of the aperture 241 may be adjusted correspondingly to achieve the required dose distribution. Of course, the scan path and the scan rate of the wafer 10 also may be adjusted correspondingly to further elastically adjust the motion of the projection of the ion beam 20 on the wafer 10. Furthermore, the size of the aperture 241 may be significantly smaller than the diameter of the wafer 10, such that the unit size of the filtered ion beam projection over the wafer 10 can be significantly reduced. Therefore, to compare with the conventional two-dimensional scan where the unit size is the size of the whole ion beam projection, the embodiment is more effective for implanting a wafer with non-uniform dose distribution.

One further advantage of the embodiment is that the dose rate control of different portions of the wafer 10 can be achieved separately. As well known, different scan rates of the ion beam 20 may induce different effects on the semiconductor structures formed in and on the wafer 10. Therefore, as discussed above, when the unit size of the projection of the filtered ion beam 20 is smaller than the size of the ion beam 20, it is easy to adjust the dose rate effect over different portions of the wafer 10.

Moreover, it is well-known that an aperture can be used to adjust the ion beam to be implanted into the wafer 10, wherein the aperture has a fixed shape and is located in a fixed position. Hence, details of the aperture 241 are omitted herein, except for main characteristics being briefly introduced. For example, a shape of the aperture 241 may be adjusted to ensure a beam current distribution of a filtered ion beam dropping to zero gradually at the edge of the aperture 241, or to ensure a current distribution of the filtered ion beam having a Gaussian distribution. As may be typical, the shape of aperture 241 may comprise one or more (e.g., combination or complex shape) of a circle, oval, ellipse and diamond. Also, the material of the aperture mechanism 240, especially the material of a part of the aperture mechanism 240 close to the aperture 241, may be graphite to minimize the possible pollution induced by collision with the ion beam 20. Besides, to further minimize possible pollution, a shield capable of preventing the aperture driving mechanism 250 from being implanted by the ion beam 20 optionally may be implemented. According to a non-illustrated embodiment, the shield may be made of graphite and located between the aperture mechanism 240 and the mass analyzer 220 for covering most of the aperture mechanism 240 and exposing essentially only the aperture 241.

As may be typical, calculation of the scan rate and the scan path, and/or even other scan parameters, can be based on an assumption that the whole aperture 241 is filled by the ion beam 20 and the whole filtered (i.e., passing through the aperture 241) ion beam is implanted into the wafer 10. The assumption almost is correct when the aperture 241 is located over the wafer 10. However, when the aperture 241 is located nearby the ends of the cross-section of the ion beam 20, the aperture 241 may not be completely filled by the ion beam. However, when the aperture 241 is located near the edge of the wafer 10, the filtered ion beam passing through the aperture 241 may not be completely projected onto the wafer 10. In such case, it is desired to correct the scan path and the scan rate, and/or even other scan parameters, according to the real ion beam passing through the aperture 241 and arriving on the wafer 10, to thereby provide what usually is referred to as an “edge correction factor.”

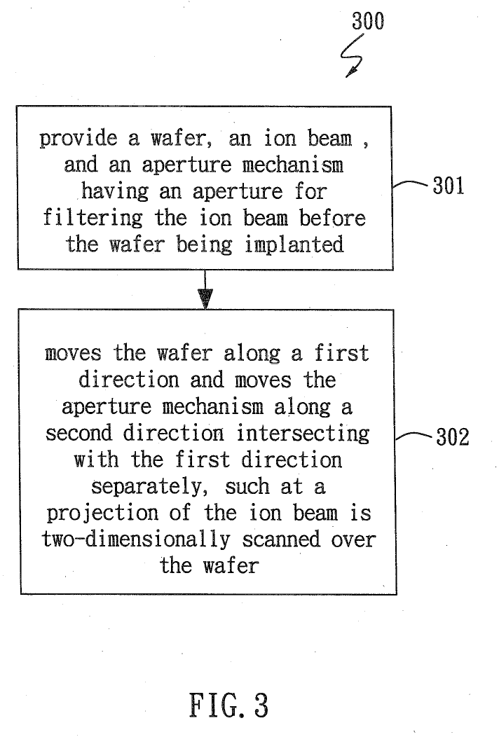

FIG. 3 shows a flow diagram of an ion implant method in accordance with an embodiment of the present invention. The ion implant method includes a step as shown in block 301 of providing a wafer, an ion beam, and an aperture mechanism (e.g., panel) having an aperture for filtering the ion beam before the wafer is implanted. As shown in block 302, the wafer is moved along a first direction and the aperture mechanism is moved along a second direction intersecting with the first direction separately, such that a projection of the ion beam is two-dimensionally scanned over the wafer.

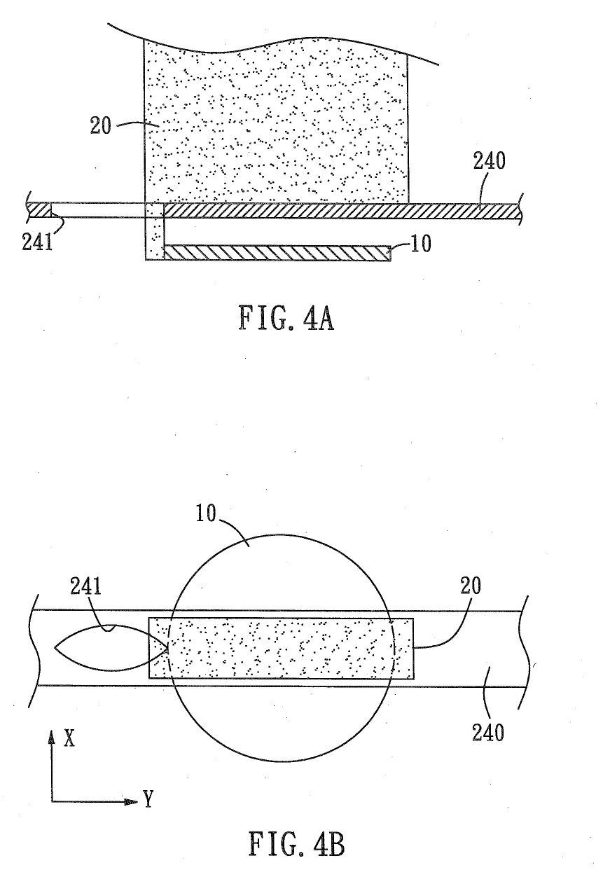

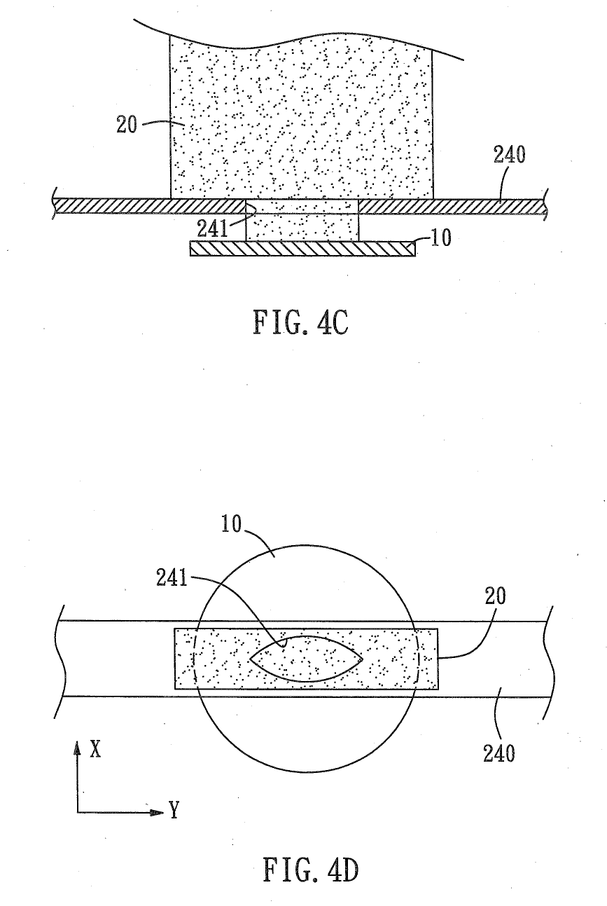

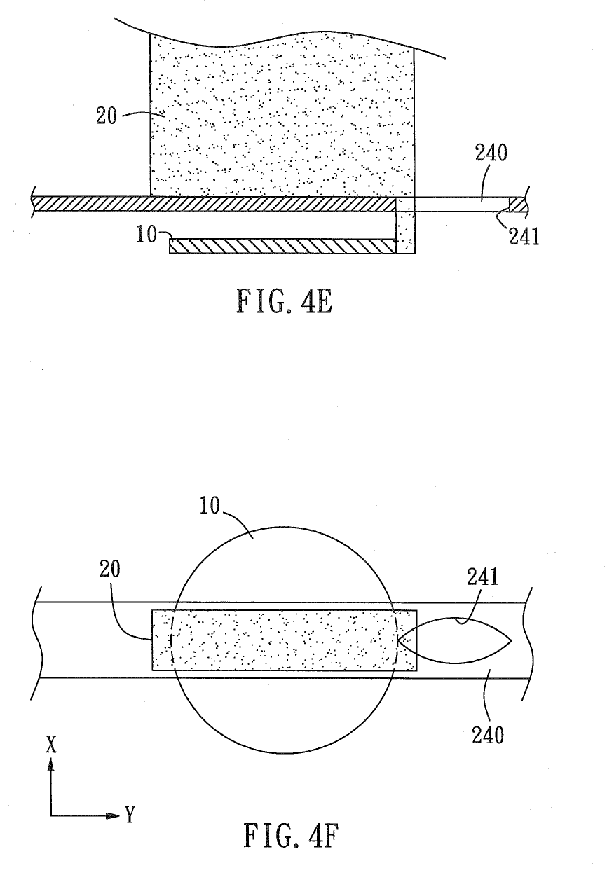

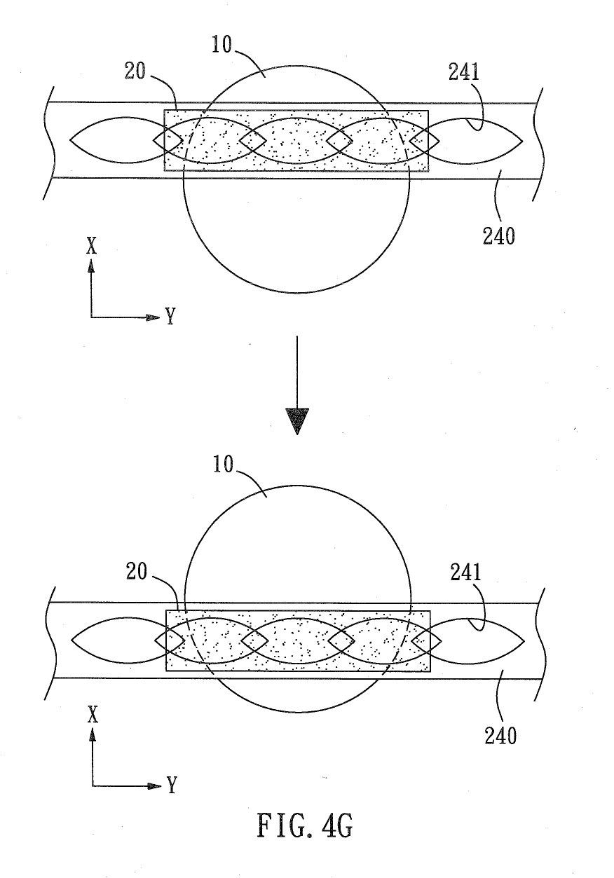

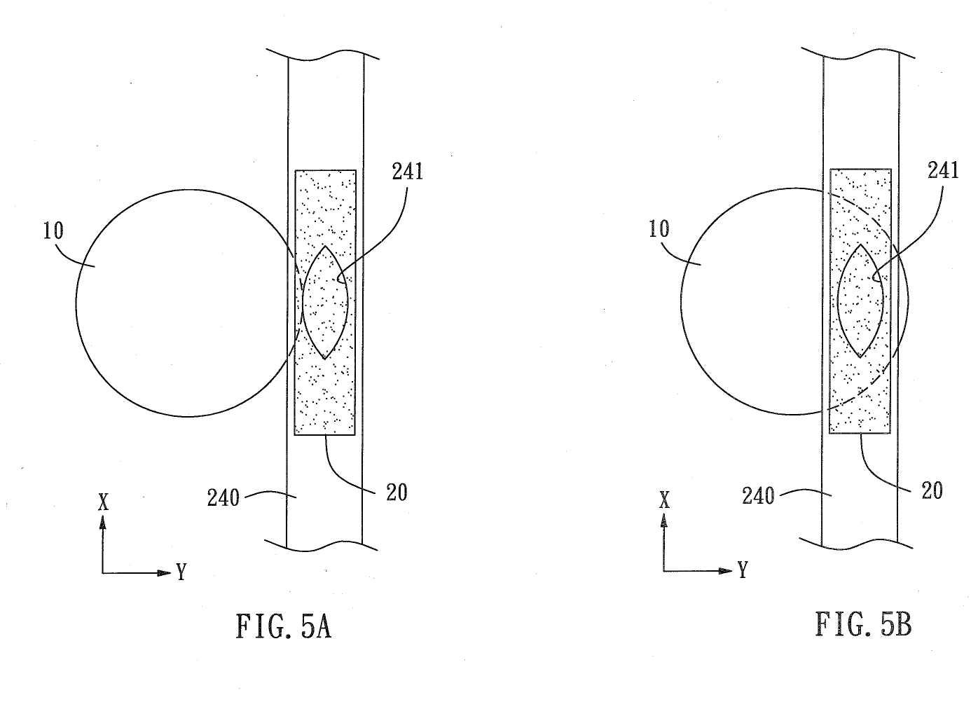

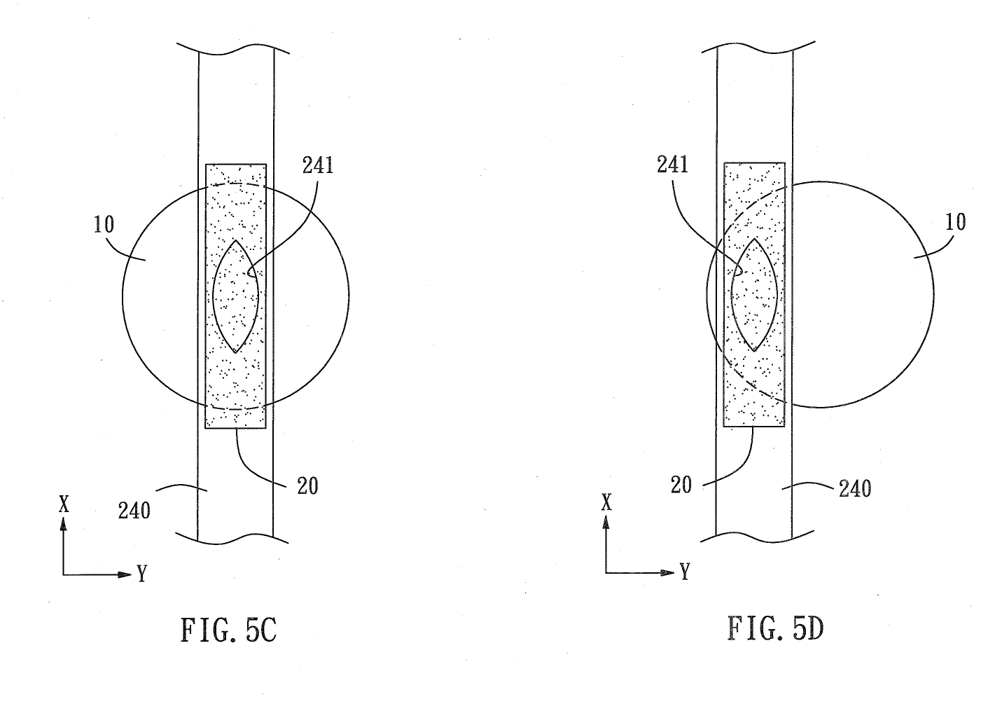

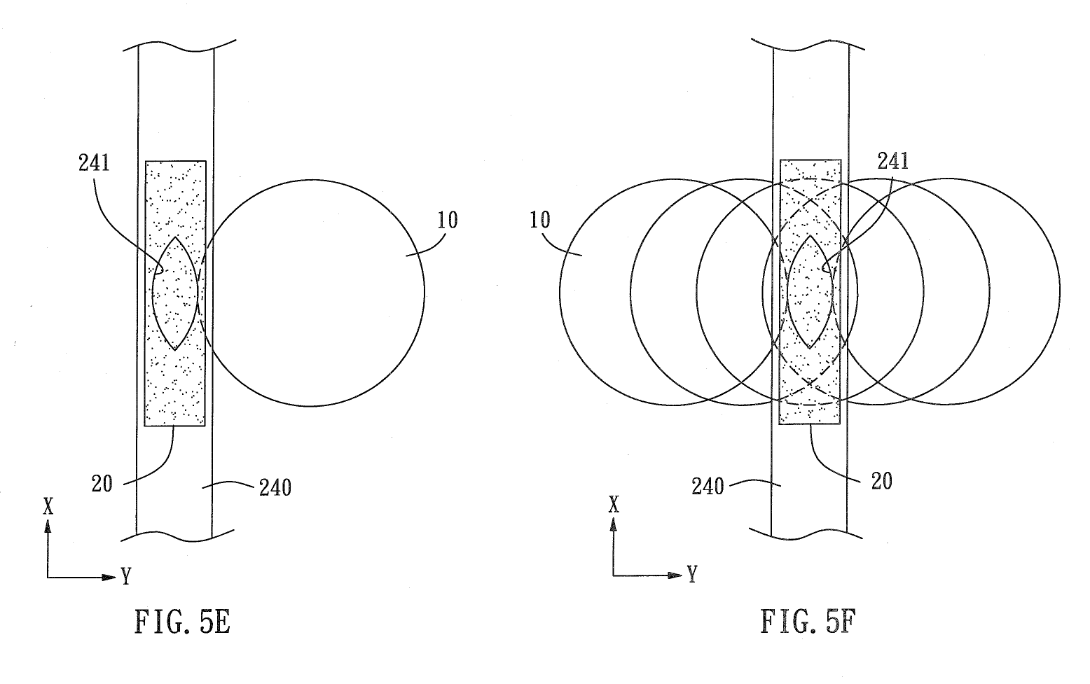

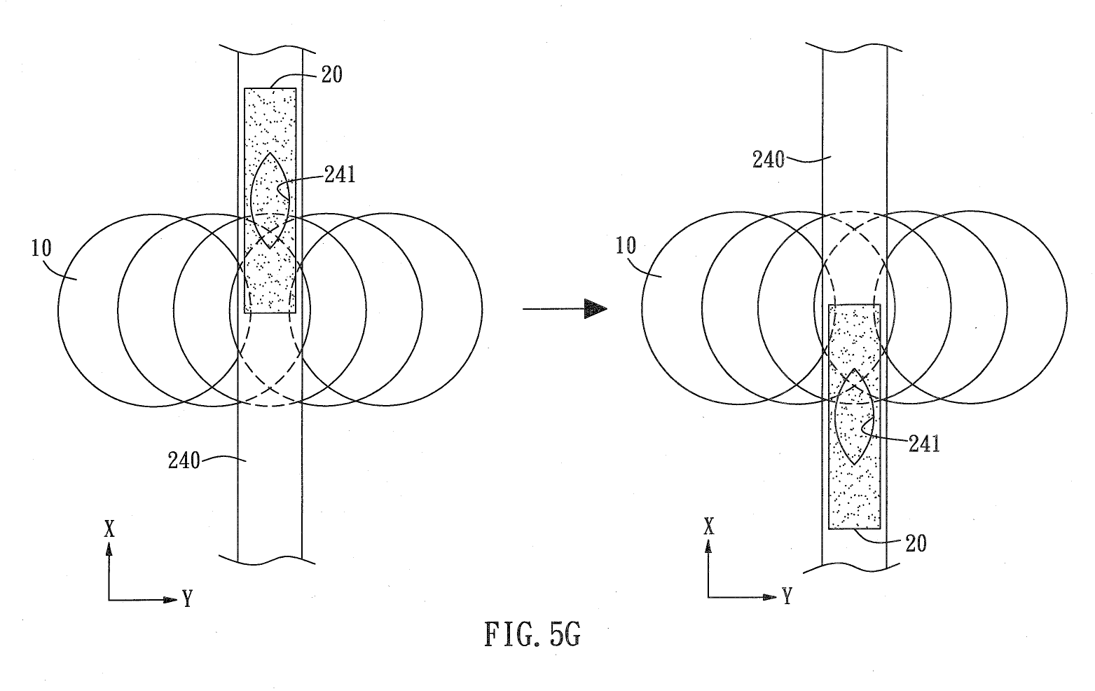

Two practical examples for block 302 are briefly discussed below with reference to FIGS. 4A-4G and FIGS. 5A-5G separately. In the embodiments, the ion beam 20 is a ribbon ion beam, and the beam height is larger than the diameter of the wafer 10. However, another non-illustrated embodiment may use a spot ion beam or a ribbon ion beam whose height is smaller than the diameter of the wafer. Of course, if the wafer diameter is smaller than the ion beam height, an additional step of moving either or both of the wafer 10 and the beam 20 in a direction of the long axis (e.g., dimension) of the ion beam projection is included to ensure proper implantation of the whole wafer 10. Herein, the additional movement of the wafer 10 or the ion beam 20 is used only to change the relative geometric relation between the wafer 10 and the ion beam 20 rather than alter the essential mechanism of the embodiment.

Referring to FIG. 4A and FIG. 4B, the aperture 241 is located in a first position of the Y-axis, and the wafer 10 is located on a side of the aperture 241 along the X-axis.

Here, as examples, the height of the ribbon beam is 350 mm if the wafer 10 is a 300 mm wafer, the uniformity of the ribbon beam is about 5% and usually not less than 1%, and the aperture 241 has an oval shape or diamond shape. To ensure that the current density of the ion beam 20 has a Gaussian distribution, the lengthwise dimension L of the aperture 241 is about 150 mm, and the lateral dimension W of the aperture 241 is about 60 mm.

Considering aperture 241, FIG. 4C and FIG. 4D show its relative movement across the ion beam 20 along the Y-axis whereby only the filtered part of ion beam 20 passing through aperture 241 is implanted into the wafer 10. As examples, the scan speed may be a function of one or more of a predefined dose, a scan number, and the edge correction factor. Continuing with FIG. 4E and FIG. 4F, the aperture 241 is further moved across the ion beam 20 until it arrives on the other side of the wafer 10. Thus, a first one-dimensional scan (e.g., in the drawing, from left to right) of the ion beam 20 on the wafer 10 is achieved (e.g., with neither the wafer 10 nor the ion beam 20 being moved). Then, optionally, the ion beam current can be measured followed by calculation of a scan parameter, such as scan rate, for the next one-dimensional scan of the ion beam 20 on the wafer 10.

Thereafter, the aperture 241 can be moved to a second position (or, alternatively, held at its current position) of the Y-axis, and the wafer 10 is positioned (e.g., in the drawing, moved up in the X-direction) for the next step. As shown in FIG. 4G, by repeating the ion implant steps mentioned above, a second one-dimensional scan (e.g., in the drawing, from right to left) of the ion beam 20 on the wafer 10 is achieved. Additional one-dimensional scans can of course be implemented. Accordingly, by implementing the one-dimensional scans, two-dimensional scanning on the wafer 10 is achieved. While not shown, alternative but not interchangeable or equivalent implementations of the invention for FIGS. 4C-4F may include movement of the wafer 10 along the X-axis (e.g., in one or more of a simultaneous, intermittent, prior, or post fashion relative to movement of the aperture 241). The one-dimensional scans can be repeated until, for example, the wafer 10 has been scanned (e.g., the entire wafer has been two-dimensionally scanned) by projection of the filtered ion beam.

Another practical embodiment is now briefly described. Referring to FIG. 5A, locate the wafer 10 in a first position of the X-axis, and locate the aperture 241 on a side of the wafer 10 along the Y-axis. Now, considering wafer 10, FIGS. 5B, 5C, and 5D show its relative movement across the ion beam 20 along the Y-axis whereby only the part of the ion beam 20 passing through aperture 241 is implanted into the wafer 10.

Referring to FIG. 5E and FIG. 5F, move the wafer 10 across the ion beam 20 until it arrives on the other side thereof. Thus, a first one-dimensional scan of the ion beam 20 on the wafer 10 is achieved (e.g., without movement of the ion beam 20). Again, it is optional to measure the ion beam current and calculate a scan parameter, such as scan rate, for the next one-dimensional scan of the ion beam 20 on the wafer 10. Subsequently, move the wafer 10 to a second position of the X-axis and move the aperture 241 to the position for the next step. Therefore, as shown in FIG. 5G, by repeating the ion implant steps mentioned above, a second one-dimensional scan of the ion beam 20 on the wafer 10 is achieved. As with the above example, additional one-dimensional scans of course can be implemented. Accordingly, when some one-dimensional scans are executed, two-dimensional scanning on the wafer 10 is achieved. While not shown, alternative but not interchangeable or equivalent implementations of the invention for FIGS. 5B-5F may include movement of the aperture 241 along the X-axis (e.g., in one or more of a simultaneous, intermittent, prior, or post fashion relative to movement of the wafer 10). The one-dimensional scans can be repeated until, for example, the wafer 10 has been scanned (e.g., the wafer has been fully two-dimensionally scanned) by projection of the filtered ion beam.

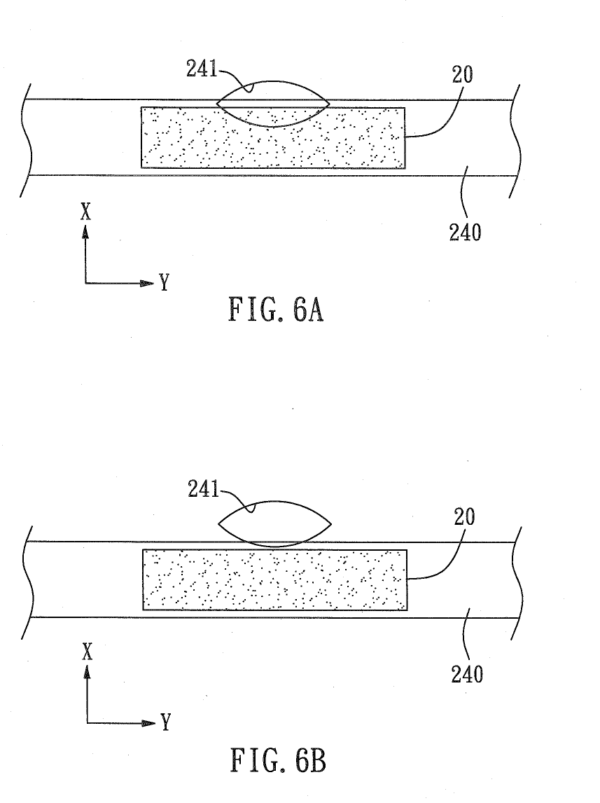

Furthermore, to more elastically adjust the shape of the filtered ion beam, the aperture 241 optionally can be slightly moved around the ion beam 20. For example, keep the aperture 241 in a fixed point of the Y-axis but slightly move aperture 241 along the x-axis. Hence, as shown in FIG. 6A and FIG. 6B, the projection of the ion beam 20 on the wafer 10 may be deformed or totally blocked. Then, different portion(s) of the wafer 10 may be implanted by different implanted ion beam(s) or even may not be implanted. Clearly, the option may be more suitable for particular situations such as non-uniform two-dimensional implantation on the wafer 10.

Although specific embodiments have been illustrated and described, it will be appreciated by those skilled in the art that various modifications may be made without departing from the scope of the present invention, which is intended to be limited solely by the appended claims.

What is claimed is:

1. An ion implanter, comprising:
an ion beam assembly capable of generating an ion beam;
a wafer driving mechanism configured to drive a wafer only along a first direction;
an aperture mechanism having an aperture for filtering said ion beam prior to said wafer being implanted; and
an aperture driving mechanism configured to drive said aperture along only a second direction intersecting with said first direction;
wherein a projection of said ion beam is two-dimensionally scanned over said wafer when said wafer and said aperture are moved along said first and second directions separately.

2. The ion implanter as set forth in claim 1, wherein said ion beam is a ribbon beam.

3. The ion implanter as set forth in claim 1, wherein said first direction is perpendicular to said second direction.

4. The ion implanter as set forth in claim 1, wherein one or more of said directions is parallel to a long axis of said projection of said ion beam.

5. The ion implanter as set forth in claim 1, wherein said aperture driving mechanism is capable of driving said aperture around said ion beam along said first direction.

6. The ion implanter as set forth in claim 1, wherein a shape of said aperture is adjusted to ensure a beam current distribution of said filtered ion beam drops to zero gradually at the edge of said aperture.

7. The ion implanter as set forth in claim 1, wherein a shape of said aperture is adjusted to ensure a beam current distribution of said filtered ion beam has a Gaussian distribution.

8. The ion implanter as set forth in claim 1, wherein a shape of said aperture is chosen from a group consisting of the following: circle, oval, ellipse and diamond.

9. The ion implanter as set forth in claim 1, further comprising a shield capable of preventing said aperture driving mechanism from being implanted by said ion beam.

10. An ion implant method, comprising:
providing a wafer, an ion beam, and an aperture mechanism having an aperture for filtering said ion beam before implantation of said wafer; and
moving said wafer along a first direction and said aperture mechanism along a second direction intersecting with said first direction separately, such that a projection of said ion beam is two-dimensionally scanned over said wafer.

11. The ion implant method as set forth in claim 10, further comprising moving said aperture mechanism along a direction intersecting said ion beam, such that a shape of said filtered ion beam is adjusted.

12. The ion implant method as set forth in claim 10, wherein said wafer is two-dimensionally scanned by said projection of said ion beam by the below steps:
(a) adjusting said aperture mechanism, such that said aperture is located under a first portion of said ion beam and above a first specific point of said wafer;
(b) adjusting said aperture mechanism, such that said aperture is moved along said second direction and at least a first portion of said wafer is implanted;
(c) moving said wafer, such that said aperture is located above a second specific point of said wafer;
(d) adjusting said aperture mechanism, such that said aperture is moved along said second direction and at least a second portion of said wafer is implanted; and
(e) repeating steps (c) and (d) in sequence, until said wafer is two-dimensionally scanned by said projection of said ion beam.

13. The ion implant method as set forth in claim 12, for any of said step (b) and step (d), further comprising slightly adjusting said aperture mechanism such that said aperture is slightly moved around said ion beam and the shape of said filtered ion beam is modified.

14. The ion implant method as set forth in claim 10, wherein said wafer is two-dimensionally scanned by said projection of said ion beam by the below steps:
(a) adjusting said aperture mechanism, such that said aperture is located under a first portion of said ion beam;
(b) moving said wafer along said first direction, such that at least a first portion of said wafer is implanted by a first filtered ion beam filtered by said aperture;
(c) adjusting said aperture mechanism, such that said aperture is moved along a second direction and said aperture is located under a second portion of said ion beam;
(d) moving said wafer along said first direction, such that at least a second portion of said wafer is implanted by a second filtered ion beam filtered by said aperture; and
(e) repeating steps (c) and (d) in sequence, until said wafer is two-dimensionally scanned by said projection of said ion beam.

15. The ion implant method as set forth in claim 14, for any of said step (b) and step (d), further comprising slightly adjusting said aperture mechanism such that said aperture is slightly moved around said ion beam and the shape of said filtered ion beam is modified.

16. The ion implant method as set forth in claim 10, wherein said ion beam is a ribbon beam.

17. The ion implant method as set forth in claim 10, wherein said second direction is parallel to a long dimension of said projection of said ion beam.

18. The ion implant method as set forth in claim 10, further comprising using a shield to prevent said aperture driving mechanism from being implanted by said ion beam.

19. The ion implant method as set forth in claim 10, further comprising adjusting a first velocity of said wafer and a second velocity of said aperture mechanism, such that said ion beam projection can be scanned through different points of said wafer by an adjustable velocity.

20. The ion implant method as set forth in claim 19, further comprising adjusting at least one scanning parameter when said aperture is not completely filled by said ion beam or said filtered ion beam is not completely projected on said wafer.
